(19) United States
(12) Patent Application Publication
(10) Pub. No.: US 2026/0247546 A1
(43) Pub. Date: Aug. 20, 2026

(54) ELECTRONIC CONTROL DEVICE

(71) Applicant: Astemo, Ltd., Chiyoda-ku, Tokyo (JP)

(72) Inventor: Junichi SHIMANE, Hitachinaka-shi, Ibaraki (JP)

(73) Assignee: Astemo, Ltd., Chiyoda-ku, Tokyo (JP)

(21) Appl. No.: 19/161,550

(22) PCT Filed: May 12, 2023
(86) PCT No.: PCT/JP2023/017864

§ 371 Date: Sep. 2, 2025

(51) Int. Cl. H05K 5/00

(52) U.S. Cl. CPC H05K 5/0052

(57) ABSTRACT

An electronic control device includes a circuit board on which a connector is mounted, a base that covers a first board surface, and a cover that covers a second board surface. The base includes a board fixing pedestal part, a cover fixing pedestal part, and a partition wall formed to be positioned at a boundary part between a connector mounting region and a circuit function region of the circuit board. A clearance between the partition wall and the first board surface in a thickness direction of the circuit board is 1.0 mm or less.

### TECHNICAL FIELD

The present invention relates to an electronic control device.

### BACKGROUND ART

Generally, a plurality of electronic control devices are mounted on a vehicle such as an automobile. An electronic control device mounted on a vehicle has a structure in which a circuit board on which electronic components are mounted is housed inside a housing.

Electronic control devices for use in automatic driving and advanced driving support systems and electronic control devices for use in central gateways are required to have dust prevention performance equivalent to IP4X. In order to satisfy this dust prevention performance, for example, it is necessary to suppress a gap between a housing that houses a circuit board and a connector mounted on the circuit board to 1.0 mm or less.

Patent Literature 1 recites a configuration, related to an in-vehicle electronic control device, in which a housing is divided into a cover (first main body) and a base (second main body), a circuit board on which a connector is mounted is attached to the base, and the circuit board is housed in a space formed by the base and the cover. Patent Literature 1 also recites a configuration in which a board surface of the circuit board on which the connector is mounted is covered with the cover, and a gap is secured between the cover and the connector.

### CITATION LIST

### Patent Literature

PTL 1: JP 2007-216836 A

### SUMMARY OF INVENTION

### Technical Problem

However, the electronic control device recited in Patent Literature 1 has a structure in which the circuit board and the cover are stacked on the base. Therefore, the gap between the cover and the connector is affected by a tolerance of the circuit board, a tolerance of the cover, and the like in addition to a tolerance of the connector. Therefore, in the electronic control device recited in Patent Literature 1, it is difficult to suppress the gap between the cover and the connector to 1.0 mm or less.

An object of the present invention is to provide an electronic control device enabling suppression of an influence of tolerances of a connector, a circuit board, and the like to be small in securing desired dust prevention performance.

### Solution to Problem

In order to solve the above problem, for example, a configuration recited in the claims is adopted.

The present application includes a plurality of means for solving the above problems, and one of them is an electronic control device including a circuit board on which a connector is mounted on a first board surface, and a base and a cover that are made of metal and house the circuit board. The first board surface of the circuit board has a connector mounting region on which the connector is mounted and a circuit function region on which a circuit functional component other than the connector is mounted. The first board surface of the circuit board is covered with the base, and a second board surface of the circuit board on a side opposite to the first board surface is covered with the cover. The base includes a plurality of board fixing pedestal parts to which the circuit board is fixed, a plurality of cover fixing pedestal parts to which the cover is fixed, and a partition wall formed to be positioned at a boundary part between the connector mounting region and the circuit function region with respect to the circuit board fixed to the plurality of board fixing pedestal parts, and a clearance between the partition wall and the first board surface in a thickness direction of the circuit board is 1.0 mm or less.

### Advantageous Effects of Invention

According to the present invention, there is provided an electronic control device enabling suppression of an influence of tolerances of a connector, a circuit board, and the like to be small in securing desired dust prevention performance.

Problems, configurations, and effects other than those described above will be clarified by the following description of an embodiment.

### BRIEF DESCRIPTION OF DRAWINGS

FIG. 1 is a perspective view illustrating an appearance of an electronic control device according to an embodiment.

FIG. 2 is a front view of the electronic control device according to the embodiment.

FIG. 3 is a bottom view of the electronic control device according to the embodiment.

FIG. 4 is a cross-sectional view taken along line A-A of the electronic control device illustrated in FIG. 2.

FIG. 5 is a bottom view of a base included in the electronic control device according to the embodiment.

FIG. 6 is an enlarged view of a part B of the electronic control device illustrated in FIG. 4.

FIG. 7 is a bottom view illustrating a state in which a cover is removed in the electronic control device according to the embodiment.

### DESCRIPTION OF EMBODIMENT

In the following, an embodiment of the present invention will be described in detail with reference to the drawings. In the present specification and the drawings, components having substantially the same function or configuration are denoted by the same reference numerals to omit redundant description.

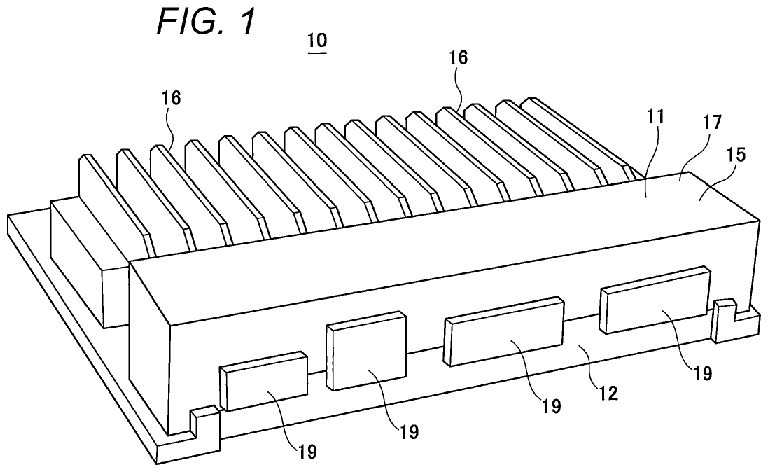

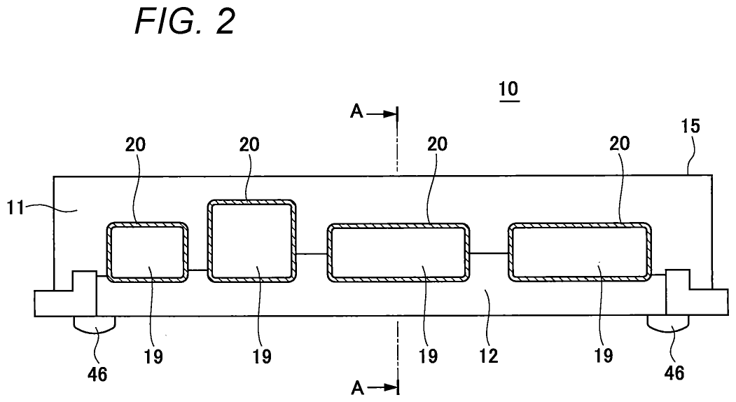

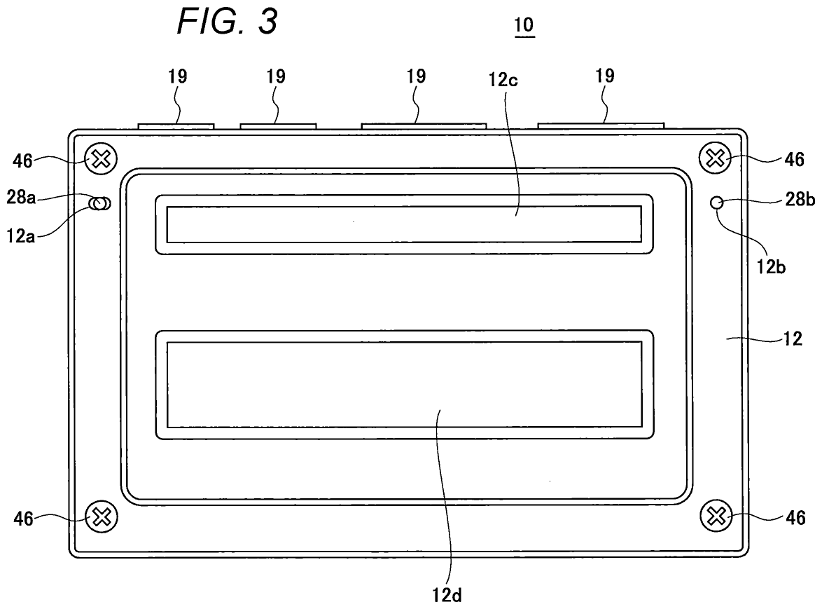

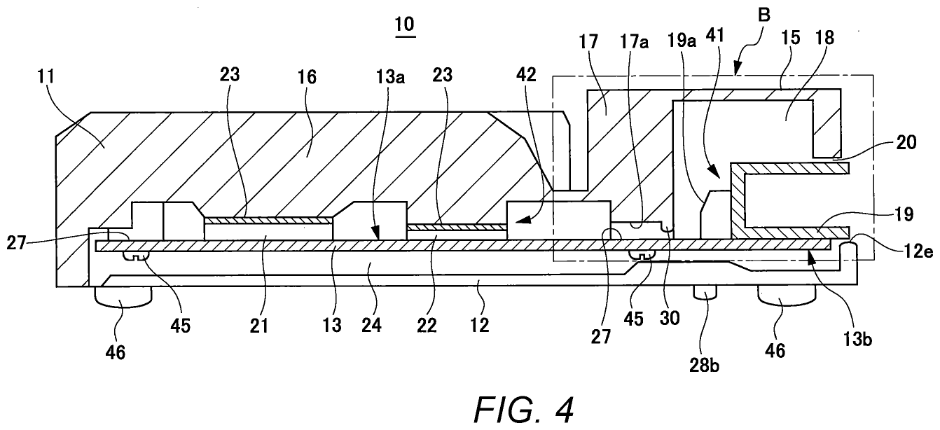

FIG. 1 is a perspective view illustrating an appearance of an electronic control device according to the embodiment. FIG. 2 is a front view of the electronic control device according to the embodiment. FIG. 3 is a bottom view of the electronic control device according to the embodiment. FIG. 4 is a cross-sectional view taken along line A-A of the electronic control device illustrated in FIG. 2.

As illustrated in FIGS. 1 to 4, an electronic control device 10 includes a base 11, a cover 12, and a circuit board 13 (FIG. 4). The electronic control device 10 is, for example, an in-vehicle electronic control device for use in automatic driving, an advanced driving support system, a central gateway, or the like.

A housing of the electronic control device 10 is a member that houses the circuit board 13 on which various electronic components are mounted in order to protect the circuit board 13. The housing is configured with the base 11 and the cover 12. The electronic control device 10 is preferably mounted on a vehicle such that the base 11 faces upward and the cover 12 faces downward.

The base 11 is a metal member. Specifically, the base 11 is a cast product obtained by, for example, aluminum die casting, and functions as a heat sink. The base 11 is formed in a rectangular shape in plan view. Component cost can be kept low by configuring the base 11 with the cast product.

In the base 11, a connector housing part 15, a plurality of heat dissipation fins 16, and a partition part 17 are integrally formed. A connector housing space 18 is formed between the connector housing part 15 and the partition part 17, and a connector 19 is housed in the connector housing space 18. The circuit board 13 has a first board surface 13a and a second board surface 13b. The first board surface 13a is disposed upward, and the second board surface 13b is disposed downward. A plurality of (four in the illustrated example) the connectors 19 is mounted on the first board surface 13a of the circuit board 13. A gap 20 (FIG. 2) is provided around each connector 19. In the present embodiment, the gap 20 around the connector 19 may not meet a requirement of IPX4, which is a desired dust prevention performance. The connector 19 has a terminal part 19a for electrical connection with a wiring pattern (not illustrated) of the circuit board 13. The plurality of heat dissipation fins 16 is a part that increases a surface area of the base 11 to enhance heat dissipation performance. The partition part 17 is formed between the connector housing part 15 and the heat dissipation fins 16.

In a formation region of the heat dissipation fin 16, the base 11 is thermally connected to electronic components 21 and 22 (FIG. 4) mounted on the circuit board 13 by a thermal interface material (TIM) 23. As a result, heat generated by the electronic components 21 and 21 can be efficiently transferred to the base 11, and the heat can be released to the outside of the base 11. The electronic components 21 and 22 are, for example, electronic components (heat generating components) including a central processing unit (CPU), a graphics processing unit (GPU), and the like having a high operation frequency and a large amount of heat generation. The electronic components 21 and 22 are mounted on the first board surface 13a of the circuit board 13 together with the plurality of connectors 19 described above.

Note that in FIG. 4, an electronic component (not shown) is mounted on the first board surface 13a of the circuit board 13 in addition to the electronic components 21 and 22, and an electronic component (not shown) is mounted also on the second board surface 13b of the circuit board 13.

The cover 12 is a metal member. The cover 12 is a sheet metal obtained by pressing (bending, shearing, drilling, etc.) a metal plate. As illustrated in FIG. 4, a board housing space 24 is formed between the cover 12 and the base 11, and the circuit board 13 is stored in the board housing space 24. Then, the first board surface 13a of the circuit board 13 is covered with the base 11, and the second board surface 13b of the circuit board 13 is covered with the cover 12.

Similarly to the base 11, the cover 12 is formed in a rectangular shape in plan view. Through holes (not illustrated) for attaching the cover 12 to the base 11 are provided at four corners of the cover 12. As illustrated in FIG. 3, positioning holes 12a and 12b, a pressing part 12c, and a reinforcing part 12d are formed in the cover 12. The positioning holes 12a and 12b are holes for positioning the cover 12 with respect to the base 11. The positioning hole 12a is a long hole, and the positioning hole 12b is a circular hole. The pressing part 12c is a part for compressing an EMI gasket (not illustrated) between the cover 12 and the circuit board 13. The reinforcing part 12d is a part for enhancing rigidity of the cover 12.

As illustrated in FIG. 4, in the vicinity of the connector 19, an end 12e of the cover 12 on a base 11 side (an upper side in FIG. 4) is disposed closer to the base 11 side (the upper side in FIG. 4) than the second board surface 13b in a thickness direction of the circuit board 13. As a result, a clearance between a lower part of the connector 19 and the end 12e of the cover 12 can be narrowed to improve the dust prevention performance.

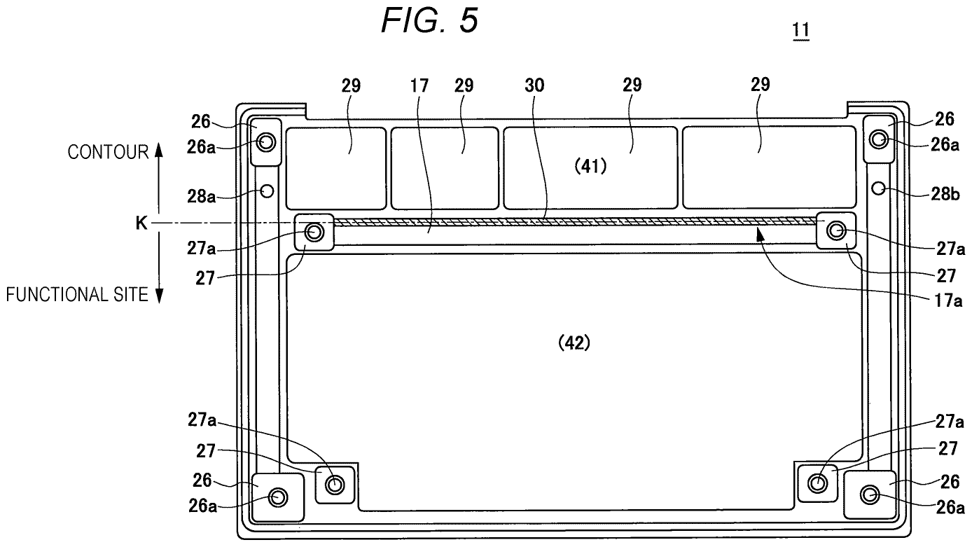

FIG. 5 is a bottom view of the base included in the electronic control device according to the embodiment.

As illustrated in FIG. 5, formed in the base 11 are a plurality of (four in FIG. 5) cover fixing pedestal parts 26, a plurality of (four in FIG. 5) board fixing pedestal parts 27, two positioning pins 28a and 28b, a plurality of (four in FIG. 5) connector housing recesses 29, and a partition wall 30 as a dust prevention wall.

The cover fixing pedestal parts 26 are formed at four corners of the base 11. The cover fixing pedestal part 26 is a pedestal part for fixing the cover 12 to the base 11. A screw hole 26a is provided at the center of the cover fixing pedestal part 26.

The plurality of board fixing pedestal parts 27 is provided inward of the plurality of cover fixing pedestal parts 26 described above. The board fixing pedestal part 27 is a pedestal part for fixing the circuit board 13 to the base 11. A screw hole 27a is provided at the center of the board fixing pedestal part 27.

The positioning pins 28a and 28b are pins for positioning the cover 12 with respect to the base 11. The positioning pins 28a and 28b are provided in the base 11 so as to correspond to the positioning holes 12a and 12b provided in the cover 12.

The plurality of connector housing recesses 29 is provided in the base 11 so as to correspond to the plurality of connectors 19 described above. The connector housing recess 29 is a part forming the above-described connector housing space 18 (FIG. 4).

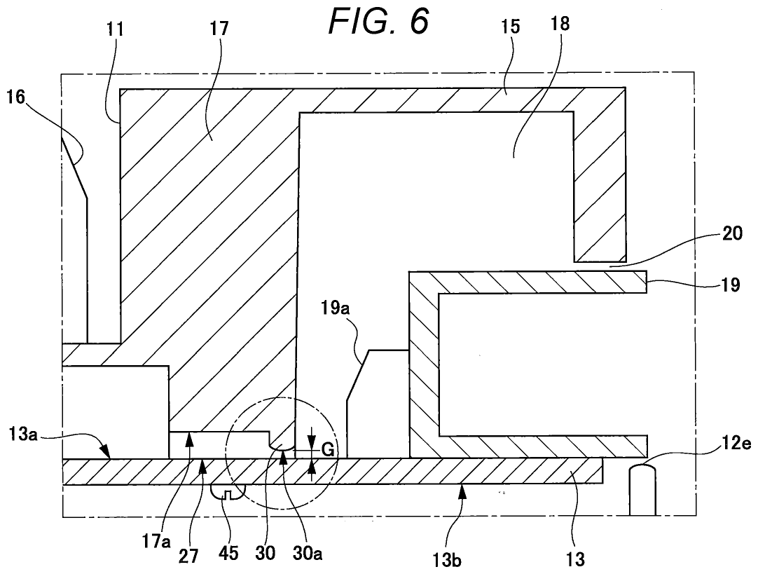

The partition wall 30 is integrally formed with the base 11 together with the cover fixing pedestal parts 26, the board fixing pedestal parts 27, the positioning pins 28a and 28b, and the connector housing recesses 29 described above. Furthermore, as illustrated in FIG. 6, the partition wall 30 is disposed at a position on a back side of the connector 19 and adjacent to the connector housing space 18. By disposing the partition walls 30 in this manner, it is possible to secure a large area of a circuit function region 42 to be described later. The partition wall 30 is formed in a convex shape on a lower surface 17a of the partition part 17. In other words, the partition wall 30 is formed so as to protrude toward the circuit board 13 side from the lower surface 17a of the partition part 17. In addition, a protruding end 30a of the partition wall 30 is disposed at a position recessed from the board fixing pedestal part 27 when viewed from the circuit board 13.

A clearance G between the partition wall 30 and the first board surface 13a of the circuit board 13 in the thickness direction (a vertical direction in FIG. 6) of the circuit board 13 is 1.0 mm or less. As a result, as illustrated in FIG. 5, dust prevention performance equivalent to IP4X is secured at a boundary part between a contour and a functional site partitioned by the partition wall 30. The partition wall 30 is not in contact with the first board surface 13a of the circuit board 13. In other words, the above clearance G is larger than zero As illustrated in FIG. 5, the partition wall 30 is formed in parallel with a longitudinal direction of the base 11. In addition, the partition wall 30 is formed to be elongated between two board fixing pedestal parts 27 disposed in the vicinity of the connector housing recesses 29 among the four board fixing pedestal parts 27 formed on the base 11.

Here, as illustrated in FIG. 4, the first board surface 13a of the circuit board 13 has a connector mounting region 41 on which the connector 19 is mounted, and the circuit function region 42 on which the electronic components 21 and 22 and other electronic components (not illustrated) are mounted. In this case, the electronic components 21 and 22 and other electronic components are equivalent to circuit functional components other than the connector. On the other hand, the partition wall 30 is formed so as to be positioned at a boundary part between the connector mounting region 41 and the circuit function region 42 with respect to the circuit board 13 fixed to the plurality of board fixing pedestal parts 27. Specifically, as illustrated in FIG. 5, the partition wall 30 is formed on the lower surface 17a of the partition part 17 positioned between the connector mounting region 41 and the circuit function region 42. In a state where the circuit board 13 is attached to the base 11, the connector mounting region 41 is disposed closer to a side of the contour than to a position K indicated by a one-dot chain line in the drawing, and the circuit function region 42 is disposed on a side of the functional site with respect to the position K. In a short side direction of the base 11, a position where the partition wall 30 is formed may be within a width of the partition part 17 opposed to the first board surface 13a of the circuit board 13.

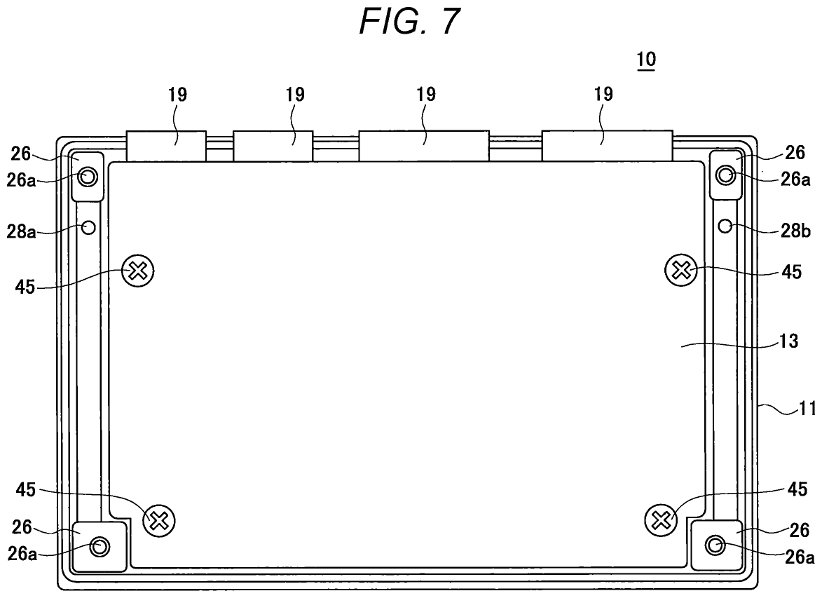

As illustrated in FIG. 7, the circuit board 13 is fixed to the base 11 by a plurality of (four in FIG. 7) board fixing screws 45 in a state where the first board surface 13a of the circuit board 13 is in contact with the plurality of board fixing pedestal parts 27. The board fixing screw 45 is engaged with the screw hole 27a (FIG. 5) of the board fixing pedestal part 27 through a through hole (not illustrated) provided in the circuit board 13. Then, the circuit board 13 is fastened and fixed to the board fixing pedestal part 27 of the base 11 by a fastening force of each board fixing screw 45. In this case, the board fixing screw 45 is equivalent to a board fastening tool for fastening and fixing the circuit board 13 to the base 11.

On the other hand, the cover 12 is fixed to the base 11 by a plurality of (four in the illustrated example) cover fixing screws 46 as illustrated in FIG. 3 in a state where the positioning pins 28a and 28b are fitted f into the positioning holes 12a and 12b and an upper surface of the cover 12 is in contact with the plurality of cover fixing pedestal parts 26. The cover fixing screw 46 is engaged with the screw hole 26a (FIG. 5) of the cover fixing pedestal part 26 through the through hole (not illustrated) provided in the cover 12. Then, the cover 12 is fastened and fixed to the cover fixing pedestal part 26 of the base 11 by a fastening force of each cover fixing screw 46. In this case, the cover fixing screw 46 is equivalent to a cover fastening tool for fastening and fixing the cover 12 to the base 11.

In the electronic control device 10 according to the present embodiment, the clearance G between the partition wall 30 and the first board surface 13a is hardly affected by a tolerance of the connector 19, the tolerance of the circuit board 13, and a tolerance of the cover 12. Therefore, in securing desired dust prevention performance (IP4X specification), an influence of the tolerances of the connector 19, the circuit board 13, and the like can be suppressed to be small. In addition, since the tolerance of the connector 19 does not affect the clearance G, a degree of freedom in connector selection can be increased, for example, a connector can be selected with priority on cost. In addition, since the partition wall 30 functions as a dust prevention wall, desired dust prevention performance can be secured without separately using a sealing material. In addition, since the configuration in which the partition wall 30 is integrally formed with the base 11 is adopted, an influence of a tolerance of the base 11 on the clearance G can be suppressed to be small.

### Modifications Etc.

The technical range of the present invention is not limited to the above-described embodiment, and includes a mode in which various modifications and improvements are added within a range in which specific effects obtained by the constituent elements of the invention and combination thereof can be derived.

For example, although in the above embodiment, as a preferable example, the configuration in which the partition wall 30 is integrally formed with the base 11 is adopted, the present invention is not limited thereto, and a configuration in which the base 11 and the partition wall 30 are separately formed and fixed by joining or the like may be adopted.

Although in the above embodiment, both the base 11 and the cover 12 are made of metal, the present invention is not limited thereto, and the base 11 may be made of metal, and the cover 12 may be made of resin.

### Reference Signs List

10 electronic control device

11 base

12 cover

13 circuit board

13a first board surface

13b second board surface

15 connector housing part

18 connector housing space

19 connector

26 cover fixing pedestal part

27 board fixing pedestal part

30 partition wall

41 connector mounting region

42 circuit function region

G clearance

1. An electronic control device comprising: a circuit board having a connector mounted on a first board surface; and a base and a cover that are made of metal and house the circuit board, wherein
the first board surface of the circuit board has a connector mounting region on which the connector is mounted and a circuit function region on which a circuit functional component other than the connector is mounted,
the first board surface of the circuit board is covered with the base, and a second board surface of the circuit board on a side opposite to the first board surface is covered with the cover,
the base includes a plurality of board fixing pedestal parts to which the circuit board is fixed, a plurality of cover fixing pedestal parts to which the cover is fixed, and a partition wall formed to be positioned at a boundary part between the connector mounting region and the circuit function region with respect to the circuit board fixed to the plurality of board fixing pedestal parts, and
a clearance between the partition wall and the first board surface in a thickness direction of the circuit board is 1.0 mm or less.

2. The electronic control device according to claim 1, wherein
an end of the cover on a side of the connector is disposed closer to a side of the base than the second board surface in the thickness direction of the circuit board.

3. The electronic control device according to claim 1, wherein
the partition wall is formed integrally with the base.

4. The electronic control device according to claim 1, wherein
the base is a cast product.

5. The electronic control device according to claim 1, wherein
the base includes a connector housing part that forms a connector housing space, and
the partition wall is disposed at a position adjacent to the connector housing space.
